(19) United States
(12) Patent Application Publication
(10) Pub. No.: US 2017/0003359 A1
(43) Pub. Date: Jan. 5, 2017

(54) MRI IMAGING USING VARIABLE DENSITY SPIRAL PLANAR COIL

(71) Applicant: THE GENERAL HOSPITAL CORPORATION, Boston, MA (US)

(72) Inventors: Matthew S. Rosen, Somerville, MA (US); Mathieu Sarracanie, Somerville, MA (US); Stanwix Paul, Crawley Way (AU)

(73) Assignee: THE GENERAL HOSPITAL CORPORATION, Boston, MA (US)

(21) Appl. No.: 15/125,654

(22) PCT Filed: Mar. 13, 2015
(86) PCT No.: PCT/US15/20515

§ 371 Date: Sep. 13, 2016

Related U.S. Application Data
(60) Provisional application No. 61/953,366, filed on Mar. 14, 2014.

(51) Int. Cl. G01R 33/341; G01R 33/567; G01R 33/563; G01R 33/44

(52) U.S. Cl. CPC G01R 33/341; G01R 33/445; G01R 33/5673; G01R 33/5635

(57) ABSTRACT

A system and method a for local coil system for performing a magnetic resonance imaging (MRI) process using an MRI system is provided. The local coil system includes a conductor extending in a spiral path along a single plane and forming a variable spiral extending from inner spirals proximate a center of the spiral path having a first density to outer spirals proximate a perimeter of the spiral path having a second density. The first density and the second density are different densities.

### CROSS-REFERENCE TO RELATED APPLICATIONS

This application is based on, claims priority to, and incorporates herein by reference in its entirety, U.S. Provisional Application Ser. No. 61/953,366, filed Mar. 14, 2014, and entitled “SYSTEM AND METHOD FOR MRI IMAGING USING A VARIABLE DENSITY SPIRAL PLANAR COIL.”

### STATEMENT REGARDING FEDERALLY SPONSORED RESEARCH

This invention was made with government support under W81XWH-11-2-076 awarded by the Department of Defense. The government has certain rights in the invention.

### BACKGROUND

The present disclosure relates to systems and methods for magnetic resonance imaging (MRI).

When a substance such as human tissue is subjected to a uniform magnetic field (polarizing field B₀), the individual magnetic moments of the excited nuclei in the tissue attempt to align with this polarizing field, but precess about it in random order at their characteristic Larmor frequency. If the substance, or tissue, is subjected to a magnetic field (excitation field B₁) which is in the x-y plane and which is near the Larmor frequency, the net aligned moment, M_{z}, may be rotated, or “tipped”, into the x-y plane to produce a net transverse magnetic moment Mₜ. A signal is emitted by the excited nuclei or “spins”, after the excitation signal B₁ is terminated, and this signal may be received and processed to form an image.

When utilizing these “MR” signals to produce images, magnetic field gradients (Gₓ, G_{y}, and G_{z}) are employed. Typically, the region to be imaged is scanned by a sequence of measurement cycles in which these gradients vary according to the particular localization method being used. The resulting set of received MR signals are digitized and processed to reconstruct the image using one of many well known reconstruction techniques.

Surface coils are a technology that is used for signal enhancement in conventional high field MRI instruments. Specifically designed for localized body regions, surface coils provide high magnetic sensitivity close to the sample resulting in high signal to noise ratios (SNR). However, their poor homogeneity generally makes them unsuitable for RF excitation, in particular when MRI sequences rely on flip angle homogeneity like steady state based sequences. Their sensitivity can be extended to larger areas when combined in multiple channel arrays, but only for tissue adjacent to the coil, and in conjunction with advanced decoupling strategies.

While many local, surface coils are available, great room exists for continued design improvements and further specialization of the coil for particular ROIs.

### SUMMARY

The present disclose provides systems and methods that overcome the aforementioned drawbacks using a homogeneous single channel surface coil for both transmit and receive operations. In particular, the coil may be advantageously used at very low magnetic fields.

In accordance with one aspect of the disclosure, a magnetic resonance imaging (MRI) system is disclosed that includes a magnet system configured to generate a static magnetic field about at least a region of interest (ROI) of a subject arranged in the MRI system and a plurality of gradient coils configured to establish at least one magnetic gradient field with respect to the static magnetic field. The system also includes a radio frequency (RF) system including a local coil. The local coil includes a conductor extending in a spiral path along a single plane and forming a variable spiral extending from inner spirals of a first density and proximate a center of the spiral path to outer spirals of a second density and proximate a perimeter of the spiral path. The first density and the second density are different densities.

In accordance with another aspect of the disclosure, a coil system is disclosed for performing a magnetic resonance imaging (MRI) process using an MRI system. The coil system includes a conductor extending in a spiral path along a single plane and forming a variable spiral extending from inner spirals proximate a center of the spiral path having a first density to outer spirals proximate a perimeter of the spiral path having a second density. The first density and the second density are different densities.

The foregoing and other advantages of the invention will appear from the following description.

### BRIEF DESCRIPTION OF THE DRAWINGS

FIG. 1 is a block diagram of an MRI system.

FIG. 2 is a block diagram of an RF system of an MRI system.

FIG. 3 is a schematic diagram of a low-field MRI system in accordance with the present disclosure.

FIG. 4 is an image of a variable-density spiral (VDS) local coil in accordance with the present disclosure that may be used with the systems of FIGS. 1-3.

FIG. 5A is a plot of a B1 field in the variable density spiral coil of FIG. 4 with a 20 turn loop.

FIG. 5B are plots of B1 field in the variable density spiral coil of FIG. 4 with a 30 turn loop.

### DETAILED DESCRIPTION OF THE PREFERRED EMBODIMENT

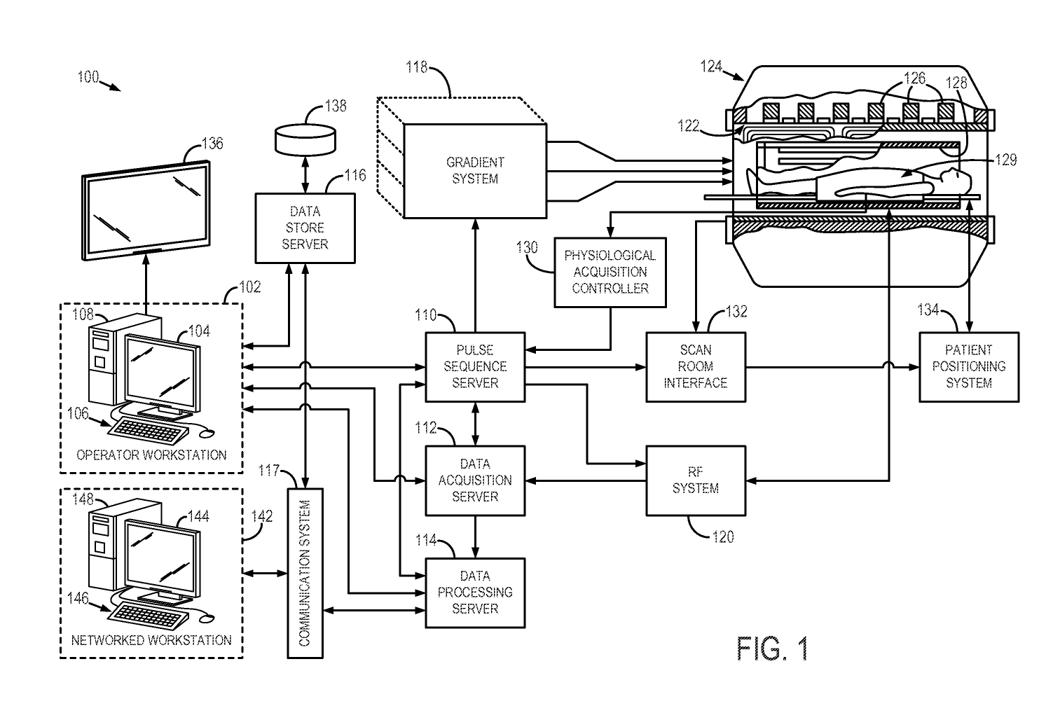

Referring particularly now to FIG. 1, an example of a magnetic resonance imaging (MRI) system 100 is illustrated. The MRI system 100 includes an operator workstation 102, which will typically include a display 104, one or more input devices 106, such as a keyboard and mouse, and a processor 108. The processor 108 may include a commercially available programmable machine running a commercially available operating system. The operator workstation 102 provides the operator interface that enables scan prescriptions to be entered into the MRI system 100. In general, the operator workstation 102 may be coupled to four servers: a pulse sequence server 110; a data acquisition server 112; a data processing server 114; and a data store server 116. The operator workstation 102 and each server 110, 112, 114, and 116 are connected to communicate with each other. For example, the servers 110, 112, 114, and 116 may be connected via a communication system 117, which may include any suitable network connection, whether wired, wireless, or a combination of both. As an example, the communication system 117 may include both proprietary or dedicated networks, as well as open networks, such as the internet.

The pulse sequence server 110 functions in response to instructions downloaded from the operator workstation 102 to operate a gradient system 118 and a radiofrequency (“RF”) system 120. Gradient waveforms necessary to perform the prescribed scan are produced and applied to the gradient system 118, which excites gradient coils in an assembly 122 to produce the magnetic field gradients Gₓ, G_{y}, and G_{z} used for position encoding magnetic resonance signals. The gradient coil assembly 122 forms part of a magnet assembly 124 that includes a polarizing magnet 126 and a whole-body RF coil 128 and/or local coil, such as a chest or hand coil 129.

RF waveforms are applied by the RF system 120 to the RF coil 128, or a separate local coil 129, in order to perform the prescribed magnetic resonance pulse sequence. Responsive magnetic resonance signals detected by the RF coil 128, or a separate local coil, such as the local coil 129, are received by the RF system 120, where they are amplified, demodulated, filtered, and digitized under direction of commands produced by the pulse sequence server 110. The RF system 120 includes an RF transmitter for producing a wide variety of RF pulses used in MRI pulse sequences. The RF transmitter is responsive to the scan prescription and direction from the pulse sequence server 110 to produce RF pulses of the desired frequency, phase, and pulse amplitude waveform. The generated RF pulses may be applied to the whole-body RF coil 128 or to one or more local coils or coil arrays, such as the local coil 129.

The RF system 120 also includes one or more RF receiver channels. Each RF receiver channel includes an RF preamplifier that amplifies the magnetic resonance signal received by the coil 128/129 to which it is connected, and a detector that detects and digitizes the I and Q quadrature components of the received magnetic resonance signal. The magnitude of the received magnetic resonance signal may, therefore, be determined at any sampled point by the square root of the sum of the squares of the I and Q components:

M=\sqrt{I²+Q²} (1);

and the phase of the received magnetic resonance signal may also be determined according to the following relationship:

$$ϕ = {tan}^{- 1} ( \frac{Q}{I} ) . \qquad ( 2 )$$

The pulse sequence server 110 also optionally receives patient data from a physiological acquisition controller 130. By way of example, the physiological acquisition controller 130 may receive signals from a number of different sensors connected to the patient, such as electrocardiograph (“ECG”) signals from electrodes, or respiratory signals from a respiratory bellows or other respiratory monitoring device. Such signals are typically used by the pulse sequence server 110 to synchronize, or “gate,” the performance of the scan with the subject's heart beat or respiration.

The pulse sequence server 110 also connects to a scan room interface circuit 132 that receives signals from various sensors associated with the condition of the patient and the magnet system. It is also through the scan room interface circuit 132 that a patient positioning system 134 receives commands to move the patient to desired positions during the scan.

The digitized magnetic resonance signal samples produced by the RF system 120 are received by the data acquisition server 112. The data acquisition server 112 operates in response to instructions downloaded from the operator workstation 102 to receive the real-time magnetic resonance data and provide buffer storage, such that no data is lost by data overrun. In some scans, the data acquisition server 112 does little more than pass the acquired magnetic resonance data to the data processor server 114. However, in scans that require information derived from acquired magnetic resonance data to control the further performance of the scan, the data acquisition server 112 is programmed to produce such information and convey it to the pulse sequence server 110. For example, during prescans, magnetic resonance data is acquired and used to calibrate the pulse sequence performed by the pulse sequence server 110. As another example, navigator signals may be acquired and used to adjust the operating parameters of the RF system 120 or the gradient system 118, or to control the view order in which k-space is sampled. In still another example, the data acquisition server 112 may also be employed to process magnetic resonance signals used to detect the arrival of a contrast agent in a magnetic resonance angiography (MRA) scan. By way of example, the data acquisition server 112 acquires magnetic resonance data and processes it in real-time to produce information that is used to control the scan.

The data processing server 114 receives magnetic resonance data from the data acquisition server 112 and processes it in accordance with instructions downloaded from the operator workstation 102. Such processing may, for example, include one or more of the following: reconstructing two-dimensional or three-dimensional images by performing a Fourier transformation of raw k-space data; performing other image reconstruction algorithms, such as iterative or backprojection reconstruction algorithms; applying filters to raw k-space data or to reconstructed images; generating functional magnetic resonance images; calculating motion or flow images; and so on.

Images reconstructed by the data processing server 114 are conveyed back to the operator workstation 102 where they are stored. Real-time images are stored in a data base memory cache (not shown in FIG. 1), from which they may be output to operator display 112 or a display 136 that is located near the magnet assembly 124 for use by attending physicians. Batch mode images or selected real time images are stored in a host database on disc storage 138. When such images have been reconstructed and transferred to storage, the data processing server 114 notifies the data store server 116 on the operator workstation 102. The operator workstation 102 may be used by an operator to archive the images, produce films, or send the images via a network to other facilities.

The MRI system 100 may also include one or more networked workstations 142. By way of example, a networked workstation 142 may include a display 144; one or more input devices 146, such as a keyboard and mouse; and a processor 148. The networked workstation 142 may be located within the same facility as the operator workstation 102, or in a different facility, such as a different healthcare institution or clinic.

The networked workstation 142, whether within the same facility or in a different facility as the operator workstation 102, may gain remote access to the data processing server 114 or data store server 116 via the communication system 117. Accordingly, multiple networked workstations 142 may have access to the data processing server 114 and the data store server 116. In this manner, magnetic resonance data, reconstructed images, or other data may exchanged between the data processing server 114 or the data store server 116 and the networked workstations 142, such that the data or images may be remotely processed by a networked workstation 142. This data may be exchanged in any suitable format, such as in accordance with the transmission control protocol (TCP), the internet protocol (IP), or other known or suitable protocols.

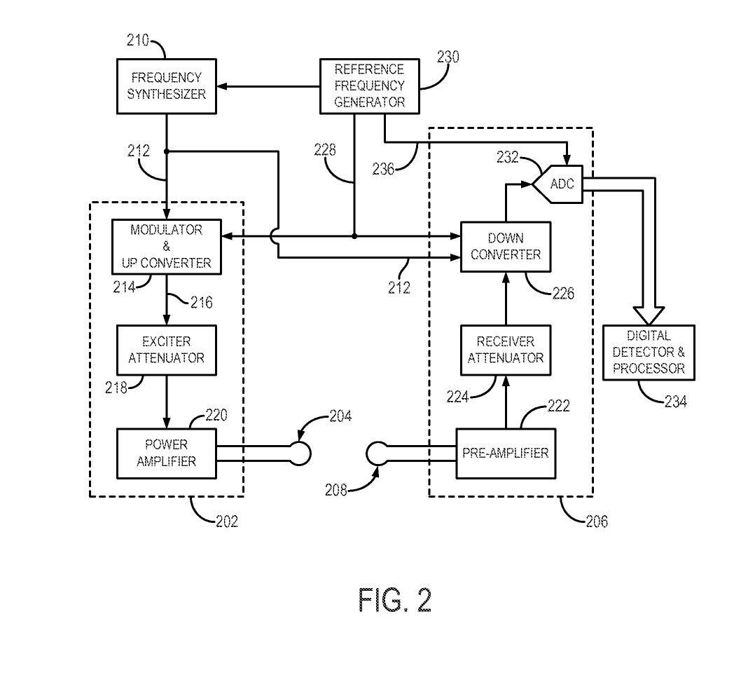

With reference to FIG. 2, the RF system 120 of FIG. 1 will be further described. The RF system 120 includes a transmission channel 202 that produces a prescribed RF excitation field. The base, or carrier, frequency of this RF excitation field is produced under control of a frequency synthesizer 210 that receives a set of digital signals from the pulse sequence server 110. These digital signals indicate the frequency and phase of the RF carrier signal produced at an output 212. The RF carrier is applied to a modulator and up converter 214 where its amplitude is modulated in response to a signal, R(t), also received from the pulse sequence server 110. The signal, R(t), defines the envelope of the RF excitation pulse to be produced and is produced by sequentially reading out a series of stored digital values. These stored digital values may be changed to enable any desired RF pulse envelope to be produced.

The magnitude of the RF excitation pulse produced at output 216 is attenuated by an exciter attenuator circuit 218 that receives a digital command from the pulse sequence server 110. The attenuated RF excitation pulses are then applied to a power amplifier 220 that drives the RF transmission coil 204.

The MR signal produced by the subject is picked up by the RF receiver coil 208 and applied through a preamplifier 222 to the input of a receiver attenuator 224. The receiver attenuator 224 further amplifies the signal by an amount determined by a digital attenuation signal received from the pulse sequence server 110. The received signal is at or around the Larmor frequency, and this high frequency signal is down converted in a two step process by a down converter 226. The down converter 226 first mixes the MR signal with the carrier signal on line 212 and then mixes the resulting difference signal with a reference signal on line 228 that is produced by a reference frequency generator 230. The down converted MR signal is applied to the input of an analog-to-digital (“ND”) converter 232 that samples and digitizes the analog signal. The sampled and digitized signal is then applied to a digital detector and signal processor 234 that produces 16-bit in-phase (I) values and 16-bit quadrature (Q) values corresponding to the received signal. The resulting stream of digitized I and Q values of the received signal are output to the data acquisition server 112. In addition to generating the reference signal on line 228, the reference frequency generator 230 also generates a sampling signal on line 236 that is applied to the ND converter 232.

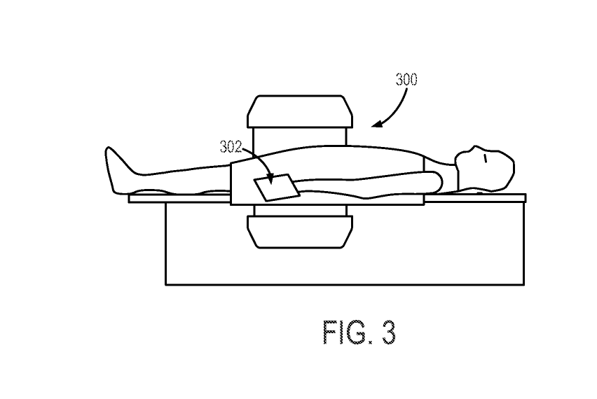

Referring to FIG. 3 a system 300 is illustrated that, instead of a 1.5 T or greater static magnetic field, utilizes a substantially smaller magnetic field. That is, as a non-limiting example, the system 300 may be less than 10 mT, such as a 6.5 mT, electromagnet-based scanner that is capable of imaging objects up to, as a non-limiting example, 15.6 cm in diameter. The system 300 may use a local coil 302 such as will be described.

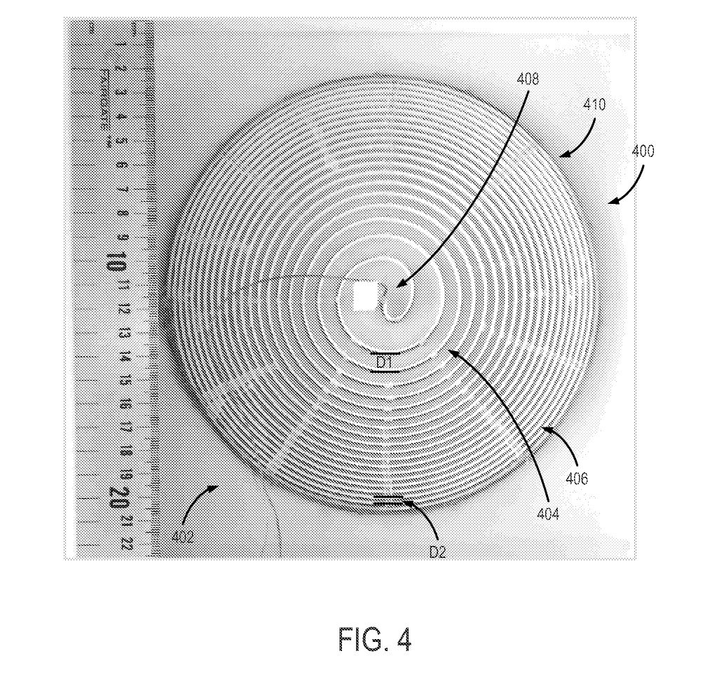

In particular, referring to FIG. 4, the above-mentioned local coil 400 may have variable-density spiral (VDS) design designed to improve B1 signal amplitude and homogeneity. In the illustrated design, the coil 400 forms a variable-density spiral that extends along a common or single plane 402. Across that single plane 402, the spiral is defined by a coil that moves from inner spirals 404 of a first density to outer spirals 406 of a second, different density. That is, inner spirals 404 nearer the center 408 of the coil 400 are of the first density (D1) and outer spirals 406 near a perimeter 410 of the coil 400 are of the second, different density (D2). In one configuration, the first density D1 of the inner spirals 404 may be less than the second density D2 of the outer spirals 406. In alternative designs, the first density D1 of the inner spirals 404 may be greater than the second density D2 of the outer spirals 406.

In the illustrated design, the variability of the density may be continuous. That is, each successive turn in the coil 400 may adjust the density. The coil 400 may maintain a constant area between each successive turn. As a non-limiting example, the coil 400 may form a spiral that features 20 turns combined in series with a 20-turn loop around the perimeter to balance the magnetic field near the perimeter 406 of the coil 400. The illustrated coil 400 covers a 20 cm circular field of view. The coil form was 3D printed in a polycarbonate.

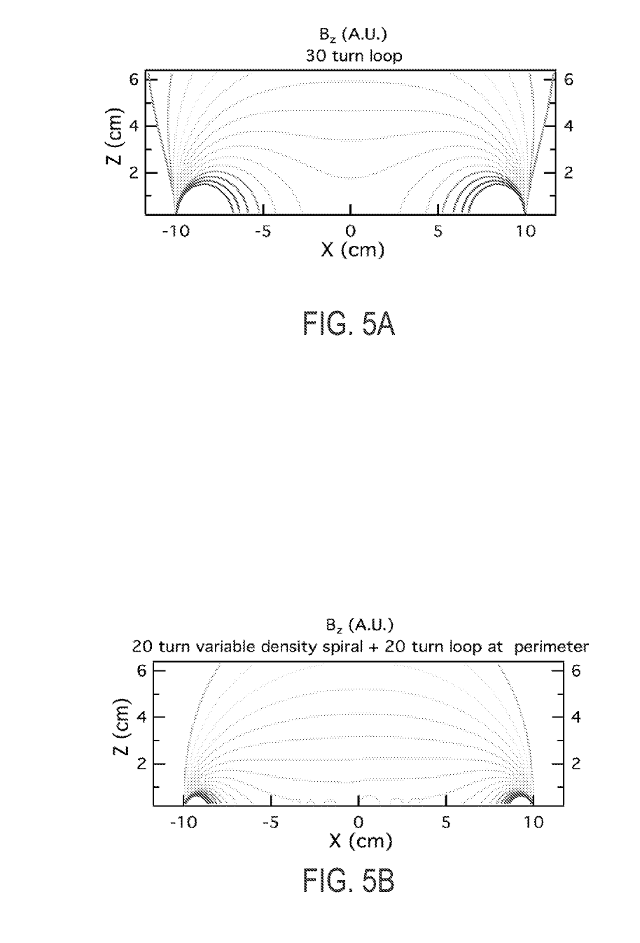

This design provides particular advantages. For example, FIG. 5A show the simulated B1 field in a VDS coil with 30-turns and FIG. 5B shows a simulated B1 filed of 20 cm diameter loop coil. Both are relative to a (6×20) cm2 plane set perpendicular to the coil surfaces. As can be seen, the variable-density spiral design shows flat magnetic field lines in the 2 cm range above the surface and maintains below 40 percent Bz deviation at ±7.5 cm along the X axis. The 20 cm loop produces curved magnetic field lines and over 70 percent Bz deviation at ±7.5 cm along the x-axis.

The VDS coil of the present disclosure was tested in vivo in a human hand at 6.5 mT using the intrinsic 1H NMR signal and a balanced steady state free precession (b-SSFP) pulse sequence. A low-field MRI (IfMRI) scanner with a bi-planar electromagnet (B0) and biplanar gradients was used for all experiments, as previously described. The 3D imaging experiment was performed with Cartesian acquisition of k-space and 50 percent undersampling rate following a Gaussian probability density function. The sequence was set with TR/TE=23.22/11.6 ms, acquisition matrix=(64×64×7), voxel size=(3×3×6) mm3, number of averages (NA)=220. The readout duration was 7.04 ms with 9091 Hz bandwidth. The total acquisition time was 20 min.

The test demonstrated a variable-density spiral surface coil for use at very-low magnetic field, achieving (3×3×6) mm3 voxel size in a (64×64×7) matrix in 20 min with a maximum image SNR of 22. The non-field cycled results demonstrate up to a factor of 2 in speed, SNR, and voxel size over those obtained with far more complex multi-channel superconducting quantum interference device (SQUID)-detected ultra-low field MRI systems using 30-80 mT prepolarization fields.

The above-described, variable-density spiral design can provide homogeneous magnetic field and high sensitivity over broad regions of interest when used for either transmit, receive, or both. As opposed to conventional surface coils that provide high sensitivity but suffer from high magnetic field inhomogeneity and need a separate coil for transmit operations, the above-described variable, spiral-design of the present disclosure can be tuned to provide high homogeneity, while maintaining high sensitivity over large field of views in a streamlined design. The coil can be used, therefore, for transmit and receive operations. So, while surface coils and surface coil arrays provide high sensitivity for material/tissue in the close vicinity of the coil, the variable density design of the present disclosure can be tuned to provide high sensitivity in bigger volumes. As opposed to surface coil arrays, the variable density spiral cover a broad field of view but does not require decoupling strategies.

Accordingly, variable-density spiral coils in accordance with the present disclosure can be used to replace current surface coils and be used without the need of a separate transmit coil, resulting in simpler, open access and lower cost devices. The variable-density coil design of the present disclosure can be advantageously used to perform MRI of the hand and extremities in patients. The variable-density spiral coil can also be used to monitor patient recovery in the case of knee or hip replacement with open access designs. Further still, the open-access, planar-design of the present variable-density spiral coil is compatible with conveyor belts and could be used to perform MRI and NMR spectroscopy for quality control in the food industry and other industrial processes. Furthers still, in the security industry, the variable-density spiral coils can be used to perform MRI and NMR spectroscopy to check for potentially dangerous chemicals in airports and areas with dense population traffic.

The present invention has been described in terms of one or more embodiments, and it should be appreciated that many equivalents, alternatives, variations, and modifications, aside from those expressly stated, are possible and within the scope of the invention.

1. A magnetic resonance imaging (MRI) system, comprising:
a magnet system configured to generate a static magnetic field about at least a region of interest (ROI) of a subject arranged in the MRI system;
a plurality of gradient coils configured to establish at least one magnetic gradient field with respect to the static magnetic field;
a radio frequency (RF) system including a local coil comprising:
a conductor extending in a spiral path along a single plane and forming a variable spiral extending from inner spirals of a first density and proximate a center of the spiral path to outer spirals of a second density and proximate a perimeter of the spiral path; and
wherein the first density and the second density are different densities.

2. The MRI system of claim 1 wherein the first density is less than the second density.

3. The MRI system of claim 1 wherein the static magnetic field is less than 10 mT.

4. The MRI system of claim 1 wherein the spiral path includes one of 20 turns or 30 turns combined in series with a 20-turn loop located proximate the perimeter and configured to balance a magnetic field near the perimeter.

5. The MRI system of claim 1 wherein the local coil is sized to image a periphery of the subject.

6. The MRI system of claim 5 wherein the local coil extends in the signal plane to provide a circular field of view of 20 cm.

7. The MRI system of claim 1 wherein the local coil is configured to produce flat magnetic field lines relative to the single plane.

8. The MRI system of claim 7 wherein the flat magnetic field lines are formed 2 cm above the single plane and maintains below 40 percent field deviation at ±7.5 cm along the single plane.

9. The MRI system of claim 1 wherein the local coil is configured to produce curved magnetic field lines relative to the single plane.

10. The MRI system of claim 9 wherein the curved magnetic field lines Provide over 70 percent deviation at ±7.5 cm along the single plane

11. A local coil system for performing a magnetic resonance imaging (MRI) process using an MRI system, the local coil system comprising:
a conductor extending in a spiral path along a single plane and forming a variable spiral extending from inner spirals proximate a center of the spiral path having a first density to outer spirals proximate a perimeter of the spiral path having a second density; and
wherein the first density and the second density are different densities.

12. The system of claim 11 further comprising a plurality of loops formed by the conductor along the perimeter of the spiral path.

13. The system of claim 11 wherein the first density is less than the second density.

14. The system of claim 11 where the spiral path is sized to image a periphery of the subject.

15. The system of claim 14 wherein the spiral path extends in the single plane to provide a circular field of view of 20 cm.

16. The system of claim 11 wherein the local coil is configured to produce flat magnetic field lines relative to the single plane.

17. The system of claim 11 wherein the local coil is configured to produce curved magnetic field lines relative to the single plane.

18. The system of claim 11 wherein the local coil maintains a constant area between each successive turn.

19. The system of claim 11 wherein the spiral path is continuously variable from the inner spirals to the outer spirals.

20. The system of claim 11 wherein the local coil is tuned to operate with a static magnetic field is less than 10 mT to carry out a magnetic resonance imaging process.
